(19) United States
(12) Patent Application Publication
(10) Pub. No.: US 2024/0395518 A1
(43) Pub. Date: Nov. 28, 2024

(54) DIAGNOSTIC DEVICE, DIAGNOSTIC METHOD, SEMICONDUCTOR MANUFACTURING EQUIPMENT SYSTEM, AND SEMICONDUCTOR EQUIPMENT MANUFACTURING SYSTEM

(71) Applicant: Hitachi High-Tech Corporation, Minato-ku, Tokyo (JP)

(72) Inventors: Shota UMEDA, Tokyo (JP); Masahiro SUMIYA, Tokyo (JP); Ryoji ASAKURA, Tokyo (JP)

(21) Appl. No.: 18/025,774

(22) PCT Filed: Feb. 7, 2022
(86) PCT No.: PCT/JP2022/004679

§ 371 Date: Mar. 10, 2023

(51) Int. Cl. H01J 37/32

(52) U.S. Cl. CPC H01J 37/32935

(57) ABSTRACT

A diagnostic device separates sensor waveform data obtained in each plasma process into components of individuals of a plurality of predefined sensor waveform change types, calculates a deterioration degree indicating a deterioration state of the part for each separated sensor waveform component based on sensor waveform components at a normal time and a diagnosis time or sensor waveform components at a deterioration time and the diagnosis time, diagnoses necessity for the maintenance of a part using the deterioration degree, executes a filtering process on time-series data of the deterioration degree calculated for each plasma process, and sets a threshold used for deterioration diagnosis for each plasma processing apparatus based on a distribution calculated using a plurality of deterioration degrees after the filter processing is performed during a learning interval from time of component maintenance to time after the process is executed a predetermined number of times.

### TECHNICAL FIELD

The present invention relates to a diagnostic device, a diagnostic method, a semiconductor manufacturing equipment system, and a semiconductor equipment manufacturing system for plasma processing apparatuses that process semiconductor wafers with plasma.

### BACKGROUND ART

A plasma processing apparatus is an apparatus that performs a plasma process in which a substance is converted into plasma and a substance on a wafer is removed by the action of the plasmalized substance in order to form fine shapes on the semiconductor wafer. In a plasma processing apparatus, maintenance such as cleaning of the inside of the apparatus and replacement of parts is performed periodically on the basis of the number of processed wafers or the like. However, unplanned maintenance work may occur due to deterioration of parts due secular variations and accumulations of reaction by-products generated depending on usage. In order to reduce the non-operating time of the apparatus due to the unplanned maintenance, it is necessary to continuously monitor deterioration states of the parts and take early countermeasures such as cleaning and part replacement according to the deterioration states.

In order to realize such early countermeasures, the diagnostic device for the plasma processing apparatus estimates deterioration degrees indicating the deterioration states of the parts using sensor waveform data that is time-series data composed of multiple sensor items sequentially obtained for each plasma process from multiple state sensors attached to the plasma processing apparatus, diagnoses whether maintenance is needed or not on the basis of the deterioration degrees, and issues an alarm as necessary. For example, WO 2018/061842 (PLT 1) discloses, “An anomaly detection device estimates a noise-removed state from a summary value by applying statistical modeling to a summary value obtained by summarizing observation values, and generates a prediction value that predicts a summary value one period ahead on the basis of the estimation. The anomaly detection device detects whether there is an anomaly in an apparatus being monitored on the basis of the prediction value.” In addition, Japanese Patent Application Laid-Open No. 2012-9064 discloses, “A learning type process anomaly diagnostic device that achieves accurate anomaly detection and anomaly diagnosis performance which is appropriate for practical process monitoring as well.”

### CITATION LIST

### Patent Literature

PLT 1: WO 2018/061842
PLT 2: Japanese Patent Application Laid-Open No. 2012-9064

### SUMMARY OF INVENTION

### Technical Problem

However, it is difficult to take effective countermeasures based on diagnosis results because false reports or oversights may occur frequently in the diagnosis of a plasma processing apparatus with the conventional technology.

In a plasma processing apparatus, the state of the apparatus may change according to the number of times of plasma processes. Accordingly, sensor waveform data, for example, may also undergo an offset change. On the other hand, when a change occurs in sensor waveform shapes due to a part deterioration separately from the abovementioned change, the sensor waveform change due to the part deterioration is buried in the unrelated sensor waveform change in the conventional technology, so that a deterioration sign may not be captured accurately, which may result in false reports or oversights.

In addition, between a plurality of plasma processing apparatuses, there may be differences in sensor waveform data and deterioration degrees calculated from the sensor waveform data due to differences in the processing histories of the apparatuses and the like. For this reason, false reports or oversights may occur in the conventional technology in which deterioration diagnosis is performed using a common threshold for a plurality of apparatuses. Furthermore, in a plasma processing apparatus, process intervals are short, and deterioration signs cannot always be confirmed for all sensor waveform data in each process, and deterioration signs may appear intermittently. In such a case, it is difficult to determine whether or not the increase of a deterioration degree is caused by a noise, that is, whether or not a part is in a deterioration state. The conventional technology that dynamically sets a threshold for each process is susceptible to noises and can generate false reports.

### Solution to Problem

In order to solve the above problem, for example, the configurations described in the claims are adopted.

The present invention includes a plurality of means for solving the above problem, and to take up an example, a diagnostic device diagnoses whether or not maintenance target parts of a plasma processing apparatus group need maintenance, and the diagnosis is performed for each plasma process using a deterioration degree indicating the deterioration state of each part calculated using sensor waveform data obtained from at least one state sensor group which each part of the plasma processing apparatus includes and a preset threshold for the deterioration degree. Furthermore, the diagnostic device separates the sensor waveform data into components of individuals of a plurality of predefined sensor waveform change types, and calculates a deterioration degree indicating the deterioration state of each part for each separated sensor waveform component on the basis of the sensor waveform components at the normal time and the diagnosis time or the sensor waveform components at the deterioration time and the diagnosis time.

In addition, the diagnostic device executes a filtering process on time-series data of deterioration degree calculated for each plasma process, and sets a threshold used for deterioration diagnosis for each plasma processing apparatus on the basis of a distribution calculated using a plurality of deterioration degrees after the filter processing is performed during a learning interval from the time of part maintenance to the time after the process is executed a predetermined number of times.

### Advantageous Effects of Invention

According to the present invention, in diagnosing necessity for the maintenance of parts of a plasma processing apparatus group, highly accurate diagnosis that permits only few false reports and few oversights can be realized, and effective countermeasures based on the diagnosis results can be taken.

Problems, configurations, and effects other than those described above will be clarified by the descriptions of the following embodiments.

### BRIEF DESCRIPTION OF DRAWINGS

FIG. 1 is an overall configuration diagram of plasma processing apparatuses and a diagnostic device according to one embodiment.

FIG. 2 is a flowchart illustrating an example of the flow of diagnostic processing according to the one embodiment.

FIG. 3 is a diagram illustrating an example of data stored in a sensor waveform storage division according to the one embodiment.

FIG. 4 is a diagram for explaining examples of separated sensor waveform types according to the one embodiment.

FIG. 5 is a diagram for explaining an example in which a plurality of sensor waveform change types of sensor waveform data due to a plurality of factors are mixed.

FIG. 6 is a diagram showing an example in which noises and intermittent deterioration signs coexist in the time-series data of deterioration degree for each process, and an example of the time-series data of deterioration degree after deterioration degree filter processing.

FIG. 7 is a diagram showing the transitions of deterioration degrees as an example of a display screen of deterioration diagnosis information according to the one embodiment.

FIG. 8 is a diagram showing a comparison of sensor waveform components as an example of a display screen of the deterioration diagnosis information according to the one embodiment.

FIG. 9 is an overall configuration diagram of plasma processing apparatuses and a diagnostic device according to another embodiment.

### DESCRIPTION OF EMBODIMENTS

Hereinafter, an embodiment of the present invention will be described with reference to the accompanying drawings. In addition, as a general rule, the same components are given the same reference signs throughout the drawings for describing the embodiment, and repeated description thereof will be omitted.

### EXAMPLE

### (1) Plasma Processing Apparatus

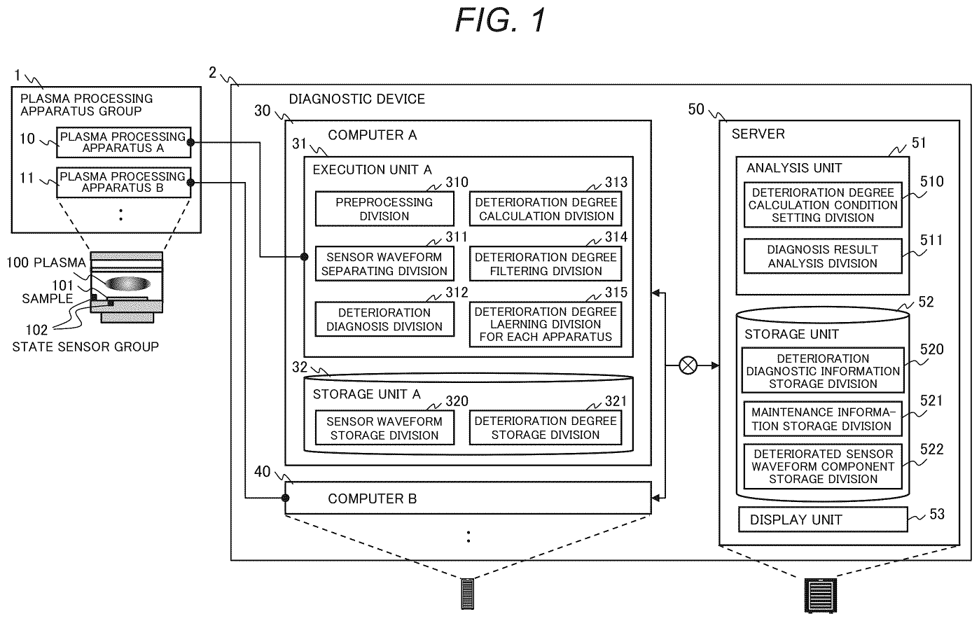

As shown in a configuration diagram of FIG. 1, a plasma processing apparatus group 1 in this example generates plasma 100 to perform a plasma process on a wafer (sample 101) according to a preset plasma process condition. The plasma processing apparatus group 1 includes plasma processing apparatuses 10 and 11 as semiconductor manufacturing apparatuses. Furthermore, each of the plasma processing apparatuses (10, 11) has a state sensor group 102 for sensing the state of a chamber (reaction chamber) and the state of parts inside each of the plasma processing apparatus (10, 11). Measured values of sensor values (for example, the values of temperature and pressure) during the execution of the plasma process or idling can be obtained as sensor waveform data.

### (2) Diagnostic Device

As shown in the configuration diagram in FIG. 1, a diagnostic device 2 includes a computer group (a computer 30, a computer 40, and the like), where each of the computer 30, the computer 40, and the like is configured by an execution unit 31 that obtains sensor waveform data and executes calculation processing corresponding to each of the plasma processing apparatuses 10 and 11 of the plasma processing apparatus group 1, and a storage unit 32 that stores information necessary for the processing performed by the execution unit 31. In addition, the diagnosis device 2 includes a server 50 configured by an analysis unit 51 that sets calculation conditions for the execution unit 31 and analyzes diagnosis results, a storage unit 52 that stores information necessary for the processing performed by the analysis unit 51, and a display unit 53. The plasma processing apparatus group 1 is connected directly or via a network to the computer group (the computer 30, the computer 40, and the like). Furthermore, the computer group (the computer 30, the computer 40, and the like) and the server 50 are connected to each other via a network. As a result, each computer can perform high-speed calculation using sensor waveform data obtained from the relevant plasma processing apparatus in the execution unit 31. In addition, the server 50 can set deterioration degree calculation conditions, analyze and display diagnosis results across the plasma processing apparatus group 1.

The execution unit 31 includes a preprocessing division 310, a sensor waveform separating division 311, a deterioration diagnosis division 312, a deterioration degree calculation division 313, a deterioration degree filtering division 314, and a deterioration degree learning division 315 for each apparatus. The storage unit 32 includes a sensor waveform storage division 320 and a deterioration degree storage division 321 in this example.

The analysis unit 51 includes a deterioration degree calculation condition setting division 510 and a diagnosis result analysis division 511 in this example. The storage unit 52 includes a deterioration diagnostic information storage division 520, a maintenance information storage division 521, and a deteriorated sensor waveform component storage division 522 in this example.

Here, the diagnosis device 2 (the computer 30 or the computer 40) and the semiconductor manufacturing apparatus (10 or 11) are connected to each other via a network, so that a semiconductor manufacturing equipment system is configured. In addition, the diagnostic device 2 (the computer 30 or the computer 40, and the server 50) and the semiconductor manufacturing device (10 or 11) are connected via a network, so that a semiconductor equipment manufacturing system is configured. The diagnostic device 2 (the computer 30 or the computer 40, and the server 50) includes a platform, on which an application for diagnosing whether or not the maintenance of the parts of the semiconductor manufacturing apparatus (10 or 11) is necessary using deterioration degrees that indicates the deterioration states of the parts, is implemented.

### (3) Diagnostic Processing

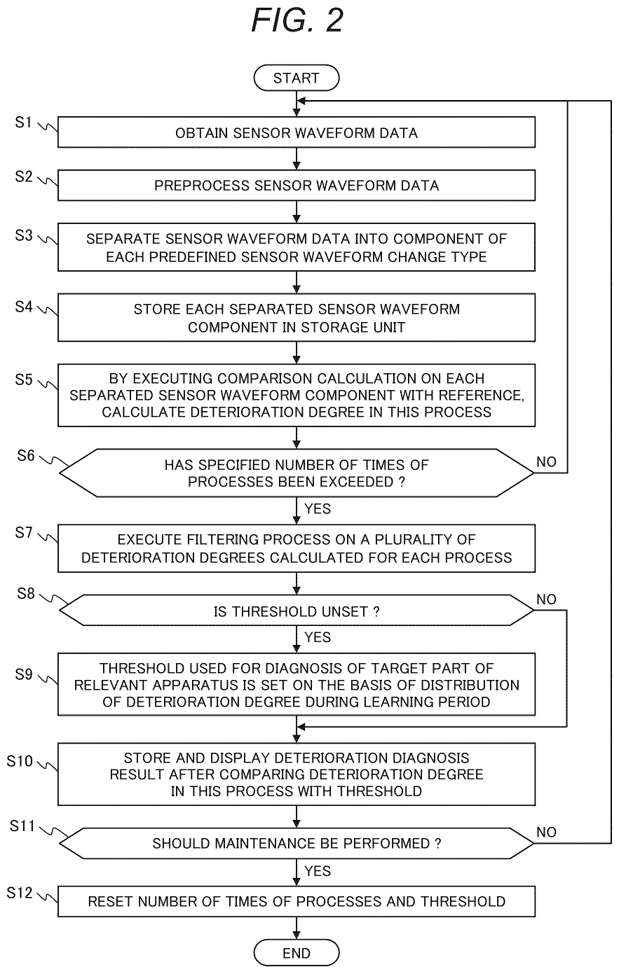

With reference to FIG. 2, an example of diagnostic processing of the necessity of the maintenance of a target part of the plasma processing apparatus group 1 performed by the diagnostic device 2 will be described. Here, it is to be noted that FIG. 2 shows a processing flow for one plasma process.

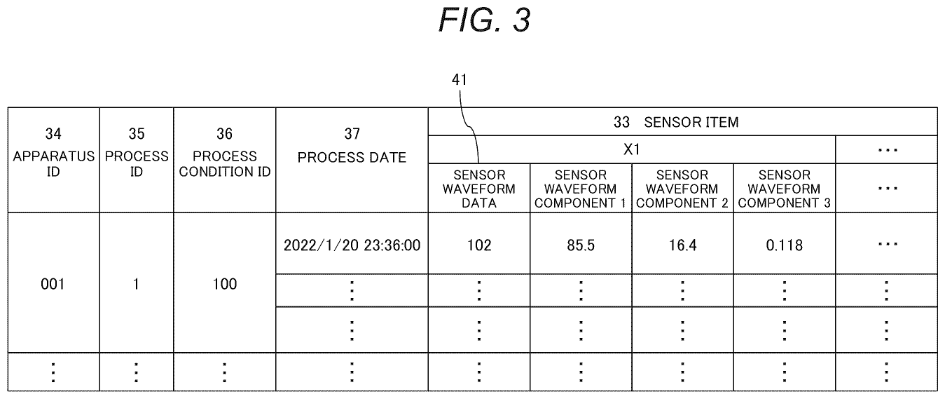

First, when completing a plasma process, the computer 30 obtains sensor waveform data 41 in the relevant plasma process and stores the sensor waveform data 41 in the sensor waveform storage division 320 (S1). FIG. 3 shows an example of the sensor waveform data to be stored. Sensor waveform data 41 includes a plurality of sensor items 33, and an obtained sensor value is stored in the column of the sensor waveform data of the column of the corresponding sensor item 33. Furthermore, the sensor waveform storage division 320 stores identification information that identifies the contents and targets of the plasma process such as an apparatus ID 34, a process ID 35, a process condition ID 36, and a process date ID 37 as well as the sensor value. The apparatus ID 34 shows information for identifying a plasma processing apparatus 10 on which the plasma process is performed. The process ID 35 shows information for identifying a wafer on which the plasma process has been performed. The process condition ID 36 shows information for identifying settings and process steps (a plurality of processes obtained by dividing the plasma process) for a plasma processing apparatus 10 when the plasma process is performed.

Next, the preprocessing division 310 obtains sensor waveform data of a sensor item used for diagnosing the diagnosis target part from the sensor waveform storage division 320 and preprocesses the sensor waveform data (S2). In the preprocess, according to contents preset by the deterioration degree calculation condition setting division 510, for example, extraction of a process condition ID 36 used for diagnosis from the sensor waveform data, extraction of a time interval within the time period of the plasma processing time, standardization of the sensor waveform data 41, and removal of missing values are performed.

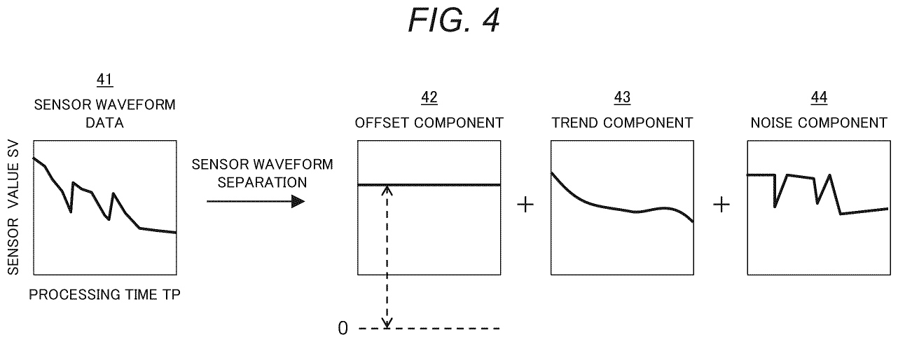

Next, the sensor waveform separating division 311 separates the sensor waveform data 41 into components of individuals of predefined sensor waveform change types (S3). An example of separating the sensor waveform data 41 into an offset component 42, a trend component 43, and a noise component 44 will be described with reference to FIG. 4. The offset component 42 is a component representing an offset term of the sensor waveform data 41, and is calculated as an average value of sensor values VS over a processing time TP, for example. Subsequently, the trend component 43 is calculated by applying a modeling method applicable to time-series data such as a Kalman filter or a Markov Chain Monte Carlo method (MCMC) to a component obtained by subtracting the offset component 42 from the sensor waveform data 41. The noise component 44 is calculated by subtracting the offset component 42 and the trend component 43 from the sensor waveform data 41. It is to be noted that when separating a sensor waveform, it is sufficient to separate a sensor waveform change type that is not related to deterioration of parts due to the change of the state of an apparatus and a sensor waveform change type that is related to deterioration signs of the parts, and there is no particular restriction on sensor waveform change types to be separated, the number of the sensor waveform change types, and a method of the separation.

Next, as shown in FIG. 3, the sensor waveform separating division 311 stores each component (42, 43, or 44) of the separated sensor waveform data 41 in the sensor waveform storage division 320 (S4).

Next, the deterioration degree calculation division 313 executes calculation for comparing the sensor waveform components of a sensor item used for diagnosing the diagnosis target part with sensor waveform component data serving as a reference, calculates a deterioration degree corresponding to the time point of the relevant processing, and stores the deterioration degree in the deterioration degree storage division 321 (S5). As for the sensor waveform component data serving as the reference, for example, a sensor waveform component group in plasma processes during a period from immediately after the maintenance of the target part until the specified number of times the process is executed can be used as a reference at a normal time. As a result, the deterioration degree can be calculated as a dissimilarity degree to the reference. In addition, by storing a sensor waveform component group in plasma processes during a period immediately before the maintenance of the target part in the deteriorated sensor waveform component storage division 522, the sensor waveform component group can also be used as a reference at a deterioration time. As a result, the deterioration degree can be calculated as a similarity degree to the reference. Machine learning methods can be applied to a method of calculating a deterioration degree as a dissimilarity degree with a reference at a normal time or a similarity degree with a reference at a deterioration time. For example, methods such as a k-nearest neighbor method, a singular spectrum transformation method, and support vector machines for time series data can be used.

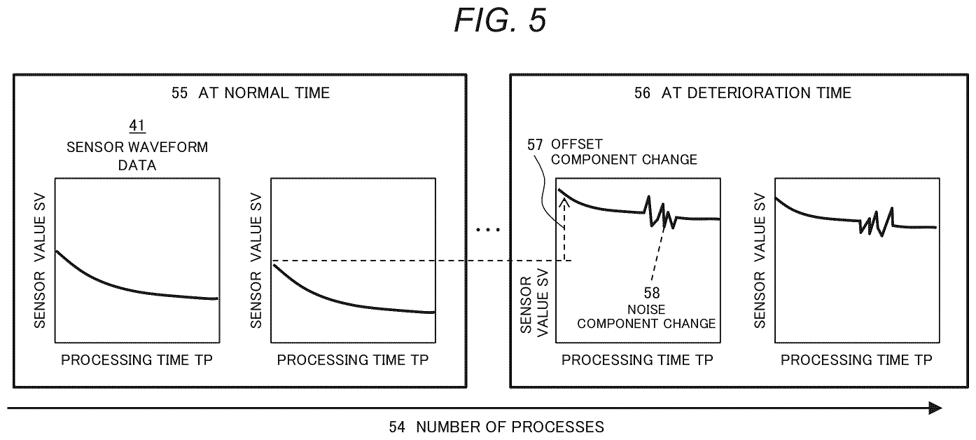

In this way, by calculating a deterioration degree using separated sensor waveform components, it becomes possible to correctly capture deterioration signs that have been buried in changes in sensor waveforms unrelated to the deterioration signs and could not have been correctly captured so far. FIG. 5 is a diagram showing an example in which a plurality of sensor waveform change types of sensor waveform data due to a plurality of factors are mixed. The horizontal axis represents the number of processes 54. Comparing sensor waveform data 41 at a normal time 55 with sensor waveform data 41 at a deterioration time 56, it turns out that an offset component change 57 and a noise component change 58 are mixed at the deterioration time 56. In the case where this offset component change 57 is a sensor waveform change caused by a change of the state of the apparatus, and the noise component change 58 is a sensor waveform change that indicates a deterioration sign, if a deterioration degree is calculated using the sensor waveform data 41 before the separation of sensor waveform components, the deterioration degree is influenced by both changes, and the deterioration sign cannot be correctly captured. In this case, by using the noise component 44 as a sensor waveform component used for calculating the deterioration degree, it is possible to correctly grasp the deterioration sign.

Next, the computer 30 determines whether sufficient sensor waveform data 41 for threshold setting, that is, for learning of the deterioration degree has been accumulated on the basis of whether or not the specified number of times of plasma processes has elapsed (S6).

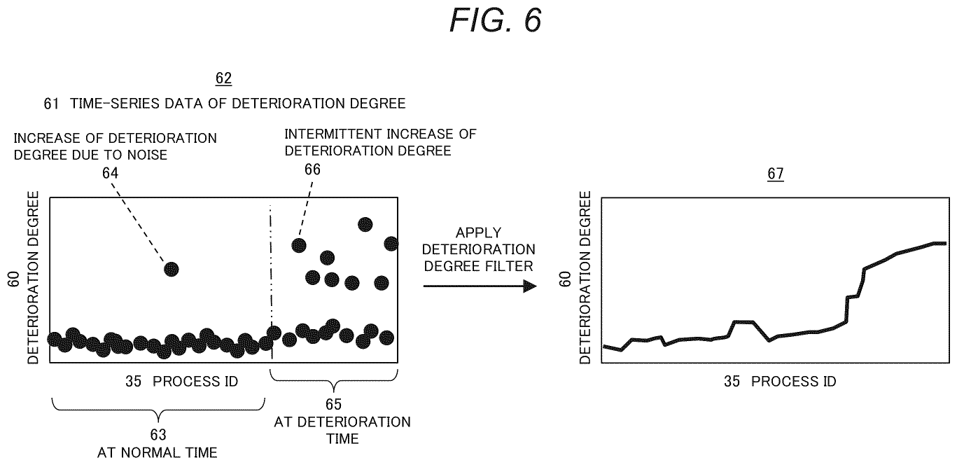

When the specified number of times of plasma processes has passed (Yes), the deterioration degree filtering division 314 executes a filtering process on the time-series data of multiple deterioration degrees calculated for each plasma process (S7). For example, in a graph 62 of the time-series data 61 of deterioration degree 60 on the left side of FIG. 6, there are deterioration degree increases 64 that occur infrequently due to noises during the early period of a normal time 63 of the process ID 35. On the other hand, in the period of a deterioration time 65, deterioration signs appear frequently, and there are deterioration degree increases 66 that occur frequently and intermittently. As shown in a graph 67 on the right side of FIG. 6, a deterioration degree filter is applied on the time-series data of such deterioration degrees in such a way that a portion where the infrequent deterioration degree increases 64 occur is regarded as noises, so that the increases of deterioration degrees regarding the portion are suppressed, and a portion where the frequent deterioration degree increases 66 occur is regarded as deterioration signs, so that deterioration degrees regarding the portion are made to continuously take high values. This makes it possible to distinguish between the noises and the states of the occurrences of intermittent deterioration signs in the diagnosis of whether or not maintenance is necessary using a threshold, which makes it possible to reduce the number of false reports. There are various methods in which the deterioration degree filter can be used, but for example, a method using the trend term of a Kalman filter, a method using a Kalman filter sequentially and using an error term, and a smoothing method can be used.

If the specified number of times of plasma processes has not been exceeded (S6: No), the flow proceeds to the obtention of sensor waveform data (S1).

After the deterioration degree filter processing for the time-series data of the deterioration degrees, it is determined whether or not a threshold used for diagnosis is unset (S8). If the threshold is not unset (has already been set) (No), the flow proceeds to S10. The threshold is unset (Yes), the deterioration degree learning division 315 for each apparatus sets the threshold (S9). First, the deterioration degree learning division 315 for each apparatus extracts a deterioration degree group during a learning interval from immediately after maintenance until the specified number of times the process is executed in the time-series data of deterioration degrees after the deterioration degree filter processing is performed. Next, the probability distribution of the deterioration degree group is estimated, and, for example, the value of the deterioration degree in a set confidence interval is set as the threshold used for diagnosing the target part of the relevant plasma processing apparatus. In the distribution estimation, if the distribution can be approximated by a normal distribution, the normal distribution is used for the estimation, and if the approximation cannot be approximated by a normal distribution, a non-normal distribution is used for the estimation using a non-normal distribution estimation method such as an MCMC. According to this processing in this configuration, a threshold is automatically set for each period from immediately after the maintenance of a target part until the next maintenance for each plasma processing apparatus, so that the influence of the difference between the apparatuses and the influence of the deterioration of diagnostic accuracy due to the obsolescence of the threshold can be removed.

Next, the deterioration diagnosis division 312 compares the deterioration degree after the application of the deterioration degree filter in the relevant plasma process with the threshold set in S9, and an alert is issued when the deterioration degree exceeds the threshold (S10). In addition, the deterioration diagnosis division 312 stores the target part ID, the used sensor item 33, the used sensor waveform components (42, 43, 44), the apparatus ID 34 to be diagnosed, the value of the deterioration degree of each process ID 35, and the threshold Information related to the diagnosis such as the degree of deterioration ratio is stored in the deterioration diagnosis information storage unit 520, and the diagnosis result is displayed on the display unit 53 so that the diagnosis result can be confirmed on the display unit 53 as necessary.

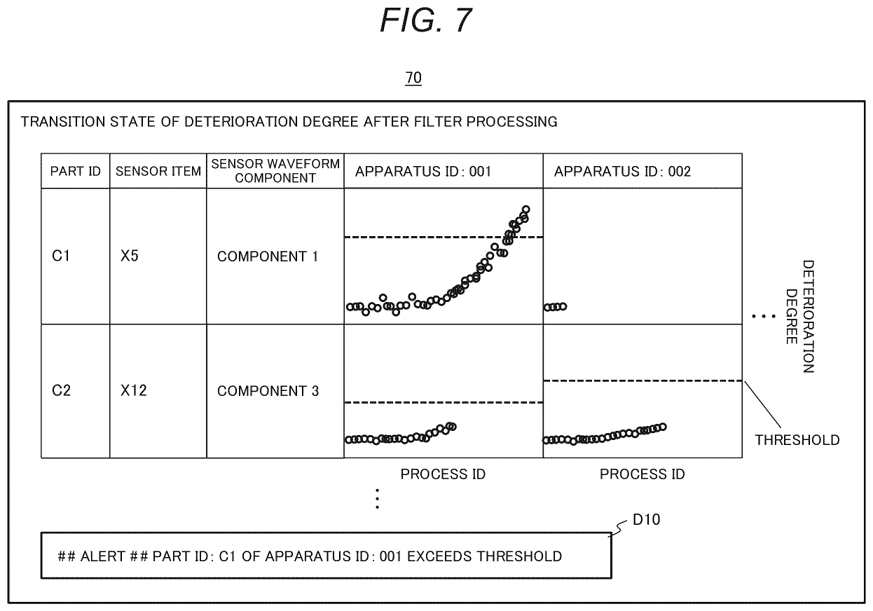

FIG. 7 is a diagram showing the transition of deterioration degree as an example of a display screen 70 of deterioration diagnosis information. For a plurality of plasma processing apparatuses 10 and 11, the transition states of deterioration degrees and threshold settings can be listed for each combination of (a part ID, a sensor item, and a sensor waveform component) used for the deterioration degree calculation. Furthermore, when a deterioration degree exceeds the relevant threshold, an alert is displayed as shown by D10. A user can see this and centrally manage the deterioration states of target parts of the plasma processing apparatus group 1, and perform early maintenance on a maintenance target part on the basis of the issued alarm, which makes it possible to reduce the non-operating time of the plasma processing apparatus group 1 due to unplanned maintenance.

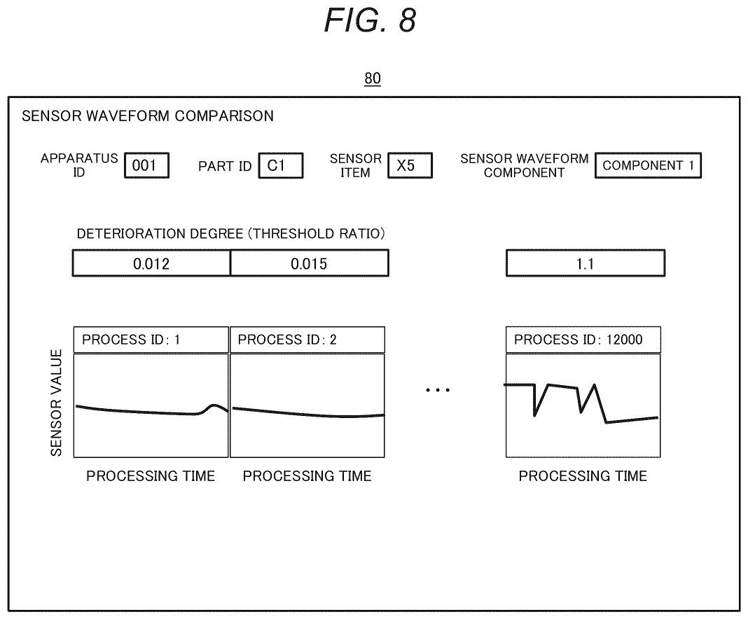

FIG. 8 is a diagram showing a comparison of sensor waveform components as an example of a display screen 80 of the deterioration diagnosis information. By designating an apparatus ID, a part ID, a sensor item, and a sensor waveform component, it is possible to list and compare sensor waveform component data for each process ID that is the source of the deterioration degree calculation. By looking at this, the user can, for example, check how the sensor waveform component changes for each sensor waveform when the deterioration degree is large, which makes it possible for the user to improve the setting of the deterioration degree calculation conditions or the like.

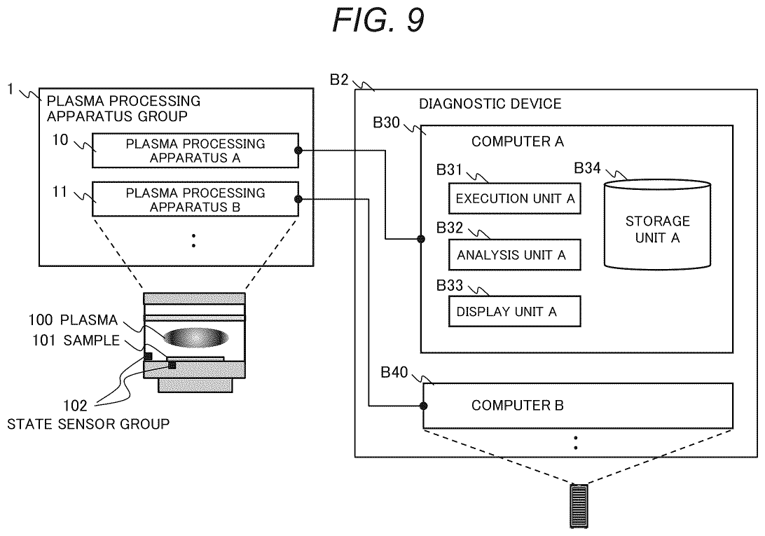

Although the example has been described above, the present invention is not limited to the above example, and can be modified in various ways without departing from the gist of the invention. For example, if it is difficult to install the server 50, the analysis unit 51, the storage unit 52, and the display unit 53 of the server 50 may be provided in the computers B30 and B40 as shown in FIG. 9 as the overall configuration.

Features of the diagnostic device, the diagnostic method, the semiconductor manufacturing equipment system, and the semiconductor equipment manufacturing system according to the example can be summarized as follows.
1) In the diagnostic device for diagnosing whether or not the maintenance of a part of the semiconductor manufacturing apparatus is needed by using a deterioration degree indicating a deterioration state of the part, an obtained sensor waveform is separated into components of individuals of a plurality of waveform change types, and a deterioration degree is calculated on the basis of the separated component of each waveform change type.
2) In 1), the component of each waveform change type is separated into an offset component, a trend component, or a noise component.
3) In 1), the component of each waveform change type is separated into a noise component.
4) In 1), a filtering process is executed on time-series data of the calculated deterioration degree, and a threshold used for diagnosing whether or not maintenance is needed is calculated on the basis of a distribution calculated using the deterioration degree on which the filtering process has been executed.
5) In 1), using the deterioration degree as an input value, a non-normal distribution is estimated by machine learning using a normal distribution or a Markov Chain Monte Carlo method, and a threshold used for diagnosing whether or not maintenance is needed is calculated on the basis of a likelihood with the normal distribution or the non-normal distribution.
6) The semiconductor manufacturing equipment system includes the diagnostic device that is described in 1) and connected to a semiconductor manufacturing apparatus via a network.
7) In the semiconductor equipment manufacturing system to which the semiconductor manufacturing apparatus is connected via a network and that includes a platform on which an application for diagnosing whether or not maintenance of a part of the semiconductor manufacturing apparatus is needed using a deterioration degree indicating the deterioration state of the part is installed, a step of separating an obtained sensor waveform into components of individuals of a plurality of waveform change types, and a step of calculating a deterioration degree on the basis of the separated component of each of the waveform change types are executed by the application.
8) The diagnostic method, which diagnoses whether or not maintenance of a part of a semiconductor manufacturing apparatus is needed using a deterioration degree indicating a deterioration state of the part, includes a step of separating an obtained sensor waveform into components of individuals of a plurality of waveform change types, and a step of calculating a deterioration degree on the basis of the separated component of each of the waveform change types.

With the use of the diagnostic device, the diagnostic method, the semiconductor manufacturing equipment system, and the semiconductor equipment manufacturing system described above, in diagnosing whether or not maintenance is necessary for a part of the plasma processing apparatus group, highly accurate diagnosis with few false reports and oversights can be achieved, and effective countermeasures based on the diagnosis results can be taken.

### REFERENCE SIGNS LIST

1 . . . plasma processing apparatus group,
2 . . . diagnostic device,
30 . . . computer,
50 . . . server,
311 . . . sensor waveform separating division,
314 . . . deterioration degree filtering division,
315 . . . deterioration degree learning division for each apparatus,
522 . . . deteriorated sensor waveform component storage division

1. A diagnostic device for diagnosing whether or not maintenance of a part of a semiconductor manufacturing apparatus is needed by using a deterioration degree indicating a deterioration state of the part,
wherein an obtained sensor waveform is separated into components of individuals of a plurality of waveform change types, and
a deterioration degree is calculated on the basis of the separated component of each waveform change type.

2. The diagnostic device according to claim 1,
wherein the component of each waveform change type is separated into an offset component, a trend component, or a noise component.

3. The diagnostic device according to claim 1,
wherein the component of each waveform change type is separated into a noise component.

4. The diagnostic device according to claim 1,
wherein a filtering process is executed on time-series data of the obtained deterioration degree, and
a threshold used for diagnosing whether or not the maintenance is needed is calculated on the basis of a distribution calculated using the deterioration degree on which the filtering process has been executed.

5. The diagnostic device according to claim 1,
wherein, using the deterioration degree as an input value, a non-normal distribution is estimated by machine learning using a normal distribution or a Markov Chain Monte Carlo method, and
a threshold used for diagnosing whether or not the maintenance is needed is calculated on the basis of a likelihood with the normal distribution or the non-normal distribution.

6. A semiconductor manufacturing equipment system comprising the diagnostic device according to claim 1 and connected to a semiconductor manufacturing apparatus via a network.

7. A semiconductor equipment manufacturing system, to which a semiconductor manufacturing apparatus is connected via a network, comprising a platform on which an application for diagnosing whether or not maintenance of a part of the semiconductor manufacturing apparatus is needed using a deterioration degree indicating a deterioration state of the part is installed,
wherein a step of separating an obtained sensor waveform into components of individuals of a plurality of waveform change types, and
a step of calculating a deterioration degree on the basis of the separated component of each of the waveform change types are executed by the application.

8. A diagnostic method for diagnosing whether or not maintenance of a part of a semiconductor manufacturing apparatus is needed using a deterioration degree indicating a deterioration state of the part, the diagnostic method comprising:
a step of separating an obtained sensor waveform into components of individuals of a plurality of waveform change types, and
a step of calculating a deterioration degree on the basis of the separated component of each of the waveform change types.
